(19) United States
(12) Patent Application Publication
(10) Pub. No.: US 2003/0165780 A1
(43) Pub. Date: Sep. 4, 2003

(54) Mesa-oxide isolation and mesa-oxide guard ring isolation methods on compound semiconductor devices and circuits

(76) Inventors: Chang-Luen Wu, Hsin-She Shiang (TW); Chih-Cheng Wang, Hsin-She Shiang (TW); Yeong-Her Wang, Hsin-She Shiang (TW); Chian-Sern Chang, Hsin-She Shiang (TW)

Correspondence Address: Alan D. Kamrath, Rider, Bennett, Egan & Arundel, LLP, Suite 2000, 333 South Seventh Street, Minneapolis, MN, 55402, US

(21) Appl. No.: 10/087,155

(22) Filed: Mar. 1, 2002

(51) Int. Cl. G03F 7/16; G03F 7/30; G03F 7/40; H01L 21/44

(52) U.S. Cl. 430/314; 430/394; 438/669

(57) ABSTRACT

A mesa-oxide isolation method comprises steps of placing a wafer in a metalorganic chemical vapor deposition (MOCVD) system or a molecular beam epitaxy (MBE) system to grow an epitaxial layer on a surface of the wafer, spinning photo-resist on an upper surface of the epitaxial layer, exposing the wafer under a light to print electric circuit pattern on a masking and soaking the wafer in a developing solution to solve and remove the photosensitive resin, etching to remove a portion of the epitaxial layer, growing an oxide layer on the area of the epitaxial layer without photo-resist by soaking the wafer in a chemical solution, removing photo-resist to form a mesa on the upper surface of the wafer, and depositing metal connections on the mesa and the wafer.

### BACKGROUND OF THE INVENTION

The present invention relates to an isolation technology using mesa-oxide isolation and mesa-oxide guard ring isolation methods for semiconductor electric circuits. The mesa-oxide isolation and mesa-oxide guard ring isolation methods significantly reduce leakage current and improve breakdown characteristics.

Referring to FIG. 1, a conventional mesa wet etching method comprises the following steps:

epitaxy: placing a wafer in a metalorganic chemical vapor deposition (MOCVD) system or a molecular beam epitaxy (MBE) system to grow an epitaxial layer on a surface of the wafer,

spinning photo-resist: spinning photo-resist on an upper surface of the epitaxial layer, the photo-resist is an acid-resistant photosensitive resin which is solidified by a ultraviolet ray,

exposing and developing: exposing the wafer under a light to print electric circuit pattern on a masking and soaking the wafer in a developing solution to solve and remove the photosensitive resin,

etching: a portion of the epitaxial layer is removed,

removing photo-resist: the photo-resist which is not exposed to the light is removed to form a mesa on the upper surface of the wafer,

metalization: depositing metal connections on the mesa and the wafer.

However, a leakage current will occur while the mesa sidewall contacts the metal connections.

Referring to FIG. 2, a conventional ion implantation method comprises the following steps:

epitaxy: placing a wafer in a metalorganic chemical vapor deposition (MOCVD) system or a molecular beam epitaxy (MBE) system to grow an epitaxial layer on a surface of the wafer,

spinning photo-resist: spinning photo-resist on an upper surface of the silicon oxide film, the photoresist is an acid-resistant photosensitive resin which is solidified by a ultraviolet ray,

exposing and developing: exposing the wafer under a light to print electric circuit pattern on a masking and soaking the wafer in a developing solution to solve and remove the photosensitive resin,

ion implantation: ion-implanting the epitaxial layer on the area without the photo-resist,

removing photo-resist: the photo-resist which is not exposed to the light is removed to form a mesa on the upper surface of the wafer,

metalization: depositing metal connections on the mesa and the wafer.

The ion implantation method prevents the wafer from contacting the metal connections efficiently, but it is expensive to use the ion implantation method.

Referring to FIG. 3, a conventional wet oxidation method comprises the following steps:

epitaxy: placing a wafer in a metalorganic chemical vapor deposition (MOCVD) system or a molecular beam epitaxy (MBE) system to grow an epitaxial layer on a surface of the wafer,

spinning photo-resist: spinning photo-resist on an upper surface of the epitaxial layer, the photo-resist is an acid-resistant photosensitive resin which is solidified by a ultraviolet ray,

exposing and developing: exposing the wafer under a light to print electric circuit pattern on a masking and soaking the wafer in a developing solution to solve and remove the photosensitive resin,

growing a thick oxide layer: growing a thick oxide layer on the area of the epitaxial layer without photoresist by soaking the wafer in a chemical solution,

removing photo-resist: the photo-resist which is not exposed to the light is removed to form a mesa on the upper surface of the wafer,

metalization: depositing metal connections on the mesa and the wafer.

However, it is difficult to increase the oxide layer to the height of the mesa. Thus a leakage current will occur while the mesa contacts the metal connections.

### SUMMARY OF THE INVENTION

The main purpose of the present invention is to apply a mesa-oxide isolation method to compound diodes, MESFETs, HFETs, HEMTs, PHEMTs, MHEMTs, HBTs, and MMICs. The mesa-oxide isolation method can be implemented on the wafers prepared by ion implantation, metalorganic-chemical vapor deposition (MOCVD), or molecular beam expitaxy (MBE). Since the oxide layer grown after mesa etching by soaking in diluted HNO3/NH4OH-solution before removing mesa photo-resist, the metal connections were not directly contacted with the doping layers of devices. This method will solve the breakdown problem of the conventional mesa technologies by wet etching. Therefore, the heavily doped layers can be used in compound devices to improve the DC and RF performances.

Another purpose of the present invention is to utilize additional wet etching or plasma etching lithography processes to implement the mesa-oxide guard ring fomations.

The present invention attempts to solve the breakdown problem caused by mesa isolation technologies, the oxidation technical issue of wet oxide isolation technologies, and the cost of using ion-implantation isolation technologies.

### BRIEF DESCRIPTIONS OF THE DRAWINGS

FIG. 1 is a schematic diagram showing a process of a conventional mesa wet etching method of the prior art;

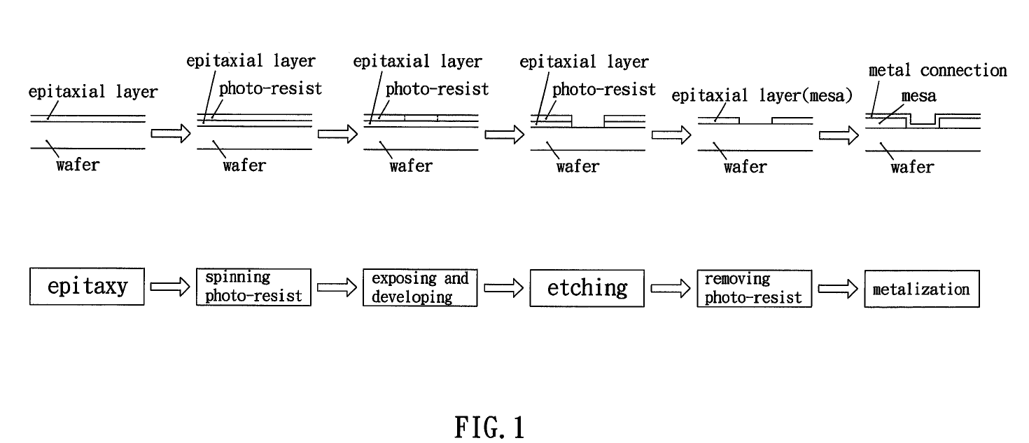

FIG. 2 is a schematic diagram showing a process of a conventional ion implantation method of the prior art;

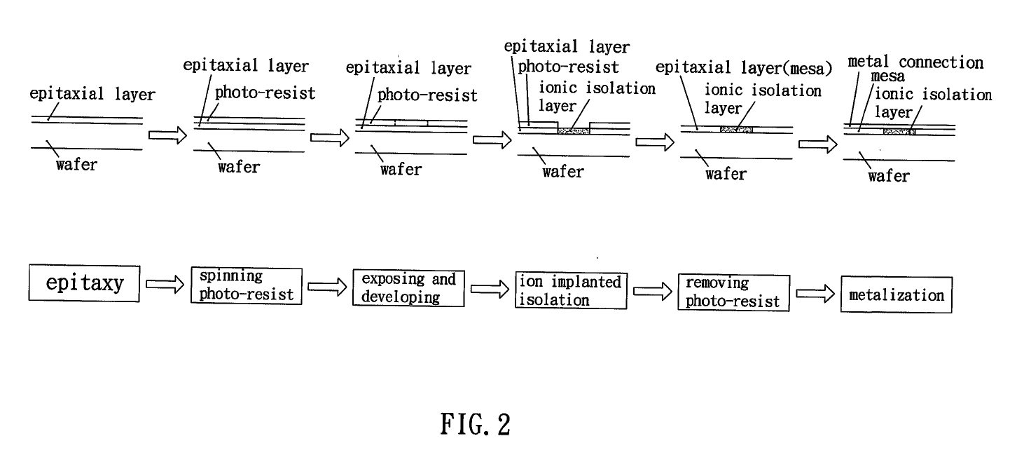

FIG. 3 is a schematic diagram showing a process of a conventional wet oxidation method of the prior art;

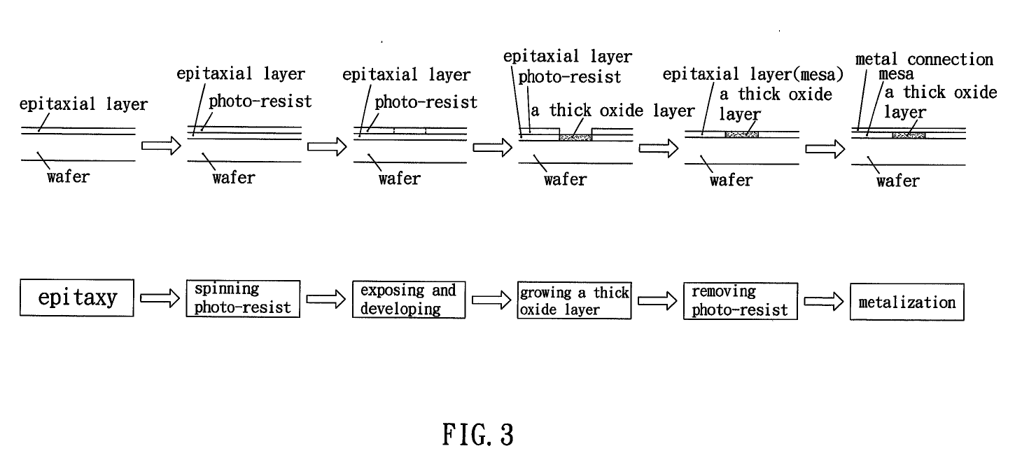

FIG. 4 is a schematic diagram showing a process of a mesa-oxide isolation method in accordance with the present invention; and

FIG. 5 is a schematic diagram showing a process of mesa-oxide guard ring isolation method in accordance with the present invention.

### DETAILED DESCRIPTION OF THE INVENTION

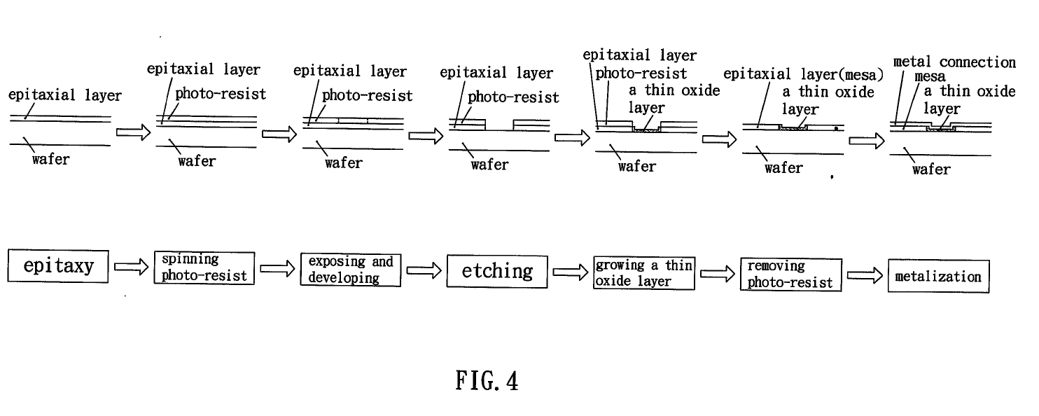

Referring to FIG. 4, a mesa-oxide isolation method comprises the following steps:

epitaxy: placing a wafer in a metalorganic chemical vapor deposition (MOCVD) system or a molecular beam epitaxy (MBE) system to grow an epitaxial layer on a surface of the wafer,

spinning photo-resist: spinning photo-resist on an upper surface of the epitaxial layer,

exposing and developing: exposing the wafer under a light to print electric circuit pattern on a masking and soaking the wafer in a developing solution to solve and remove the photosensitive resin,

etching: a portion of the epitaxial layer is removed,

growing a thin oxide layer: growing a thin oxide layer on the area of the epitaxial layer without photo-resist by soaking the wafer in a chemical solution,

removing photo-resist: the photo-resist which is not exposed to the light is removed to form a mesa on the upper surface of the wafer,

metalization: depositing metal connections on the mesa and the wafer.

The mesa-oxide isolation (MOI) method is superior to the conventional mesa isolation to reduces the leakage current significantly and to improve breakdown characteristics.

The mesa-oxide isolation (MOI) method is superior to the conventional wet oxidation method, because it is easy to grow a thin oxide layer. As we know, it is difficult to grow a thick oxide layer by the wet oxidation.

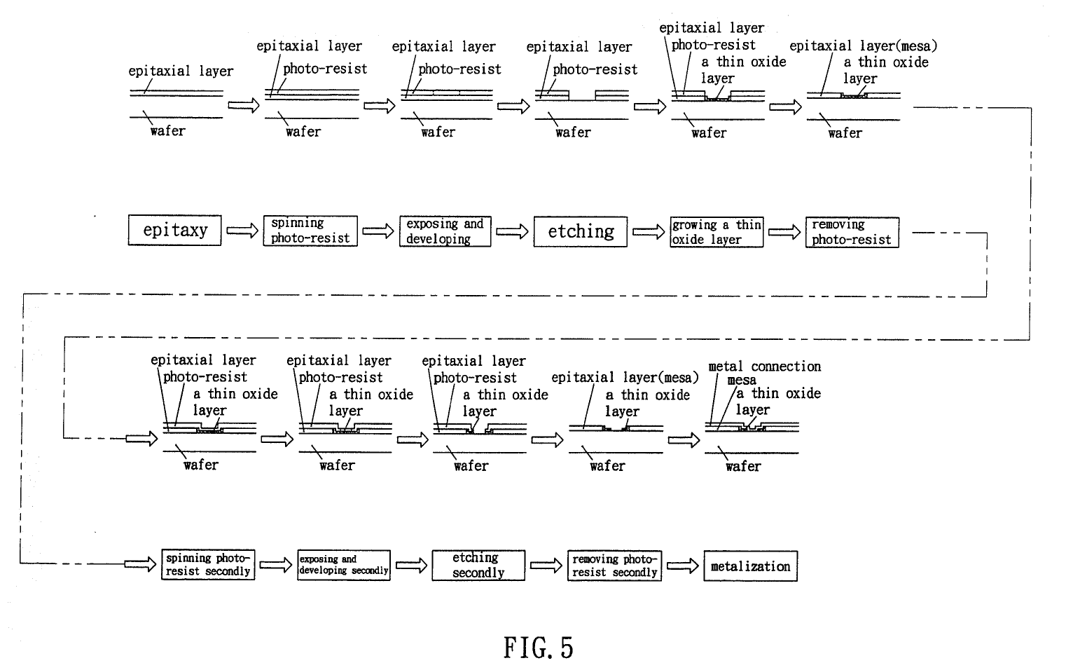

Referring to FIG. 5, a mesa-oxide guard ring isolation method comprises the following steps:

epitaxy: placing a wafer in a metalorganic chemical vapor deposition (MOCVD) system or a molecular beam epitaxy (MBE) system to grow an epitaxial layer on a surface of the wafer,

spinning the first photo-resist: spinning the first photo-resist on an upper surface of the epitaxial layer,

exposing and developing at the first time: exposing the wafer under a light to print electric circuit pattern on a masking and soaking the wafer in a developing solution to solve and remove the photosensitive resin,

etching at the first time: a portion of the epitaxial layer is removed,

growing a thin oxide layer: growing a thin oxide layer on the area of the epitaxial layer without photoresist by soaking the wafer in a chemical solution,

removing photo-resist at the first time: the photoresist which is not exposed to the light is removed to form a mesa on the upper surface of the wafer,

spinning the second photo-resist: spinning the second photo-resist on an upper surface of the epitaxial layer,

exposing and developing at the second time: exposing the wafer under a light to print electric circuit pattern on a masking and soaking the wafer in a developing solution to solve and remove the photosensitive resin,

etching at the second time: a portion of the thin oxide layer is removed,

removing photo-resist at the second time: the photoresist which is not exposed to the light is removed to form a mesa on the upper surface of the wafer and to form an oxide ring on the surrounding of the mesa,

metalization: depositing metal connections on the mesa and the wafer.

I claim:

1. A mesa-oxide isolation method comprises steps of:
epitaxy: placing a wafer in a metalorganic chemical vapor deposition (MOCVD) system or a molecular beam epitaxy (MBE) system to grow an epitaxial layer on a surface of the wafer,
spinning photo-resist: spinning photo-resist on an upper surface of the epitaxial layer,
exposing and developing: exposing the wafer under a light to print electric circuit pattern on a masking and soaking the wafer in a developing solution to solve and remove the photosensitive resin,
etching: a portion of the epitaxial layer is removed,
growing a thin oxide layer: growing a thin oxide layer on the area of the epitaxial layer without photoresist by soaking the wafer in a chemical solution,
removing photo-resist: the photo-resist which is not exposed to the light is removed to form a mesa on the upper surface of the wafer,
metalization: depositing metal connections on the mesa and the wafer.

2. A mesa-oxide guard ring isolation method comprises steps of:
epitaxy: placing a wafer in a metalorganic chemical vapor deposition (MOCVD) system or a molecular beam epitaxy (MBE) system to grow an epitaxial layer on a surface of the wafer,
spinning the first photo-resist: spinning the first photo-resist on an upper surface of the epitaxial layer,
exposing and developing at the first time: exposing the wafer under a light to print electric circuit pattern on a masking and soaking the wafer in a developing solution to solve and remove the photosensitive resin,
etching at the first time: a portion of the epitaxial layer is removed,
growing a thin oxide layer: growing a thin oxide layer on the area of the epitaxial layer without photoresist by soaking the wafer in a chemical solution,
removing photo-resist at the first time: the photoresist which is not exposed to the light is removed to form a mesa on the upper surface of the wafer,
spinning the second photo-resist: spinning the second photo-resist on an upper surface of the epitaxial layer,
exposing and developing at the second time: exposing the wafer under a light to print electric circuit pattern on a masking and soaking the wafer in a developing solution to solve and remove the photosensitive resin,
etching at the second time: a portion of the thin oxide layer is removed,
removing photo-resist at the second time: the photoresist which is not exposed to the light is removed to form a mesa on the upper surface of the wafer and to form an oxide ring on the surrounding of the mesa,
metalization: depositing metal connections on the mesa and the wafer.
